(19) United States
(12) Patent Application Publication
(10) Pub. No.: US 2020/0287068 A1
(43) Pub. Date: Sep. 10, 2020

(54) FLEXIBLE LAMINATE OF PHOTOVOLTAIC CELLS AND METHOD FOR MANUFACTURING SUCH A FLEXIBLE LAMINATE

(71) Applicant: TOTAL SOLAR INTERNATIONAL, Courbevoie (FR)

(72) Inventors: Valerick CASSAGNE, Limours (FR); Raphael DINELLI, Olonne-Sur-Mer (FR)

(73) Assignee: TOTAL SOLAR INTERNATIONAL, Courbevoie (FR)

(21) Appl. No.: 16/756,659

(22) PCT Filed: Oct. 18, 2018
(86) PCT No.: PCT/EP2018/078650

§ 371 Date: Apr. 16, 2020

(30) Foreign Application Priority Data
Oct. 20, 2017 (FR) 1759895

(51) Int. Cl. H01L 31/048; H01L 31/055

(52) U.S. Cl. CPC H01L 31/0481; H01L 31/055

(57) ABSTRACT

A flexible laminate of photovoltaic cells is provided, including a layer of photovoltaic cells connected to one another; a frontal layer and a rear layer encapsulating the layer of photovoltaic cells, the frontal layer and the rear layer sandwiching the layer of photovoltaic cells; and at least one transparent layer of polymer-based varnish deposited on one of the frontal layer and/or the rear layer, the at least one transparent layer being disposed on an outside of the flexible laminate and being configured to ensure a protection of the flexible laminate. A method for manufacturing a flexible laminate of photovoltaic cells is also provided.

The present invention relates to the field of photovoltaic panels. More particularly, the present invention relates to laminated photovoltaic panels. Moreover, the present invention relates also to a method for manufacturing such a laminate forming the photovoltaic panel.

Because of the reduction in the reserve of fossil-fuel energies and the increasing pollution generated by the consumption of these fossil fuel energies, renewable energy resources and energy consumption within a sustainable development framework are increasingly being turned to. This trend naturally leads to prioritizing the renewable energies such as solar energy. It is now conventional practice to install photovoltaic panels, notably on the roofs of businesses, public buildings, or simply on the roofs of individual homes to supply energy to equipment in the home concerned, or to resell this energy to a supplier.

The composition of the photovoltaic panels has to be thin enough to limit their weight and bulk, which makes it possible for example to load them on a vehicle, be incorporated in the structure of a vehicle, or be incorporated in light building structures. So as to adapt to widely varying places and operate while being subject to climatic attacks, vibrations and mechanical stresses in general over long periods, often more than twenty years, the modules have to have a structure that is strong enough while being lightweight. To resolve these constraints, it is known practice to encapsulate photovoltaic cells in encapsulation layers comprising a polymerizable resin in order to ensure the bond between the different layers that make up the photovoltaic panel without the usual glass plate for the standard modules which makes the photovoltaic panel heavier. In that way, the photovoltaic cells are protected both from a mechanical point of view and from outside conditions, air, water and ultraviolet radiations.

Furthermore, the form of the support can vary significantly, and notably have a dished receiving surface. It is therefore necessary to be able to adapt the form of the photovoltaic panel to that of the support. Generally, when designing and manufacturing an encapsulated photovoltaic panel, also called laminated photovoltaic panel, there is an effort to ensure that the encapsulated panel has all the following properties:
minimal thickness,
lightness,
deformability,
flexibility,
translucency,
seal-tightness,
reliability.

Different laminated photovoltaic panels and different methods for manufacturing such photovoltaic panels are known from the prior art. However, the durability of these laminated photovoltaic panels is fairly limited because the different materials used for the encapsulation deteriorate and are also subject to external attacks such as scratches, ultraviolet radiation or even acid attacks depending on the geographic area in which these photovoltaic panels are installed for example. Furthermore, the climatic conditions can damage the laminate forming the photovoltaic panel, and notably create a separation of the different layers forming this laminate, this phenomenon is also known as delamination, which is detrimental to the performances of the photovoltaic panel, even prevents it from operating in optimal safety conditions.

The aim of the present invention is therefore to at least partially remedy the various drawbacks of the prior art mentioned above by proposing a flexible laminate offering an enhanced resistance to external conditions, and notably climatic conditions, while retaining all the abovementioned requisite properties.

Another objective of the present invention is to propose a flexible laminate of photovoltaic cells for which the maintenance and repair operations are simplified.

Another objective of the present invention, different from the preceding objective, is to propose a method for manufacturing such a flexible laminate.

In order to at least partially achieve at least one of the abovementioned objectives, the subject of the present invention is a flexible laminate of photovoltaic cells comprising at least:
a layer of photovoltaic cells connected to one another, and
a frontal layer and a rear layer encapsulating the layer of photovoltaic cells, said frontal and rear encapsulation layers sandwiching the layer of photovoltaic cells,
   the flexible laminate further comprising at least one transparent layer of polymer-based varnish deposited on one of the frontal and/or rear encapsulation layers, said at least one transparent layer of varnish being disposed on the outside of the flexible laminate and being configured to ensure a protection of the flexible laminate.

The presence of at least one transparent layer of polymer-based varnish makes it possible to protect the different layers that make up this flexible laminate and notably prevents their separation or their delamination. Thus, the presence of this transparent layer of varnish makes it possible to prevent the efficiency losses of such laminated photovoltaic panels over time, these efficiency losses being potentially due to the deteriorations of the components of the flexible laminate provoked by the outside conditions, such as, for example, the climatic conditions.

Furthermore, the use of a layer of varnish disposed on one of the frontal and/or rear encapsulation layers makes it possible to facilitate and simplify the operations of maintenance and repair on this layer of varnish, by filling any holes or scratches which can be formed in this layer of varnish under the effect of solid objects being thrown onto this layer of varnish, for example once this flexible laminate is installed.

The flexible laminate according to the present invention can also comprise one or more of the following features taken alone or in combination.

The transparent layer of varnish is composed of a polymer-based varnish chosen from among the varnishes of polyurethane type, the varnishes of acrylic type, the varnishes of polyester type, the varnishes of silicone type, or even the varnishes of epoxy type.

According to a first aspect, the varnish can comprise at least one additive that absorbs or reflects the ultraviolet radiation.

According to a second aspect, the varnish can comprise at least one self-extinguishing additive.

According to a third aspect, the varnish can comprise at least one additive that makes it possible to enhance the diffusion of light.

According to a fourth aspect, the varnish can comprise at least one additive that makes it possible to convert photons of certain spectral ranges to the current-conversion spectral ranges of the photovoltaic cells.

According to yet another aspect, the varnish can also comprise an additive such as pigments when it is intended to be deposited on the rear encapsulation layer.

Optionally or in addition, the varnish can comprise glass balls.

According to a variant, the flexible laminate can further comprise a first and a second intermediate layer disposed respectively between the frontal layer and the layer of photovoltaic cells and between the rear encapsulation layer and the layer of photovoltaic cells.

According to this variant, the first and second intermediate layers can be composed of a dry glass fiber fabric.

According to a particular embodiment, the frontal and rear encapsulation layers are layers of glass fiber fabric pre-impregnated with an encapsulation resin.

According to one aspect, the flexible laminate comprises at least one lateral edge covered with said at least one transparent layer of varnish.

Also a subject of the present invention is a method for manufacturing a flexible laminate of photovoltaic cells comprising a layer of photovoltaic cells connected to one another, a frontal layer and a rear layer encapsulating the layer of photovoltaic cells, said method comprising a finishing step in which a polymer-based varnish, in liquid form, is applied to at least one of the frontal or rear encapsulation layers.

The use of a varnish in liquid form makes it possible to facilitate the manufacture of such a flexible laminate, and therefore limit the production costs of these flexible laminates. Furthermore, the use of a varnish in liquid form also makes it possible to easily modify the thickness of this layer of varnish. Furthermore, the use of a varnish in liquid form makes it possible to have access to a larger panel for the solvents that can be used and also access to the different liquid phase deposition techniques. Moreover, this finishing step makes it possible to protect the edges of the flexible laminate by creating a moisture-tight barrier making it possible to notably prevent the separation of the different layers forming the flexible laminate.

According to a first aspect, the finishing step is performed by spraying varnish on the frontal or rear encapsulation layer.

According to a second aspect, the finishing step is performed by deposition of the varnish with a brush on the frontal or rear encapsulation layer.

According to a third aspect, the finishing step is performed by curtain coating on the frontal or rear encapsulation layer.

According to a particular embodiment, the method can comprise an additional step of surface texturing of the varnish.

According to an aspect of this particular embodiment, the additional step of surface texturing of the varnish can be performed during the polymerization of this varnish.

According to this particular embodiment, the additional texturing step is performed by calendering.

Other advantages and features of the present invention will become more clearly apparent on reading the following description, given in an illustrative and nonlimiting manner, and the attached drawings in which:

FIG. 1 is a plan schematic representation of a flexible laminate,

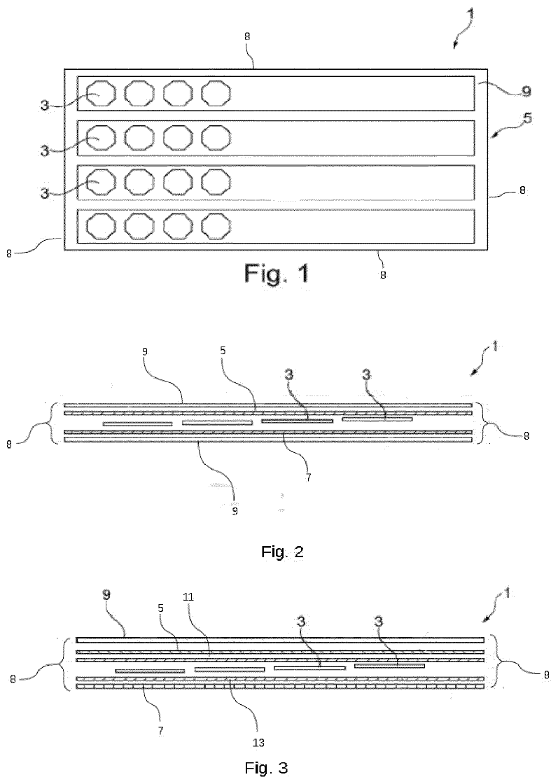

FIG. 2 is a cross-sectional schematic representation of a flexible laminate according to a first embodiment,

FIG. 3 is a cross-sectional schematic representation of a flexible laminate according to a second embodiment, and

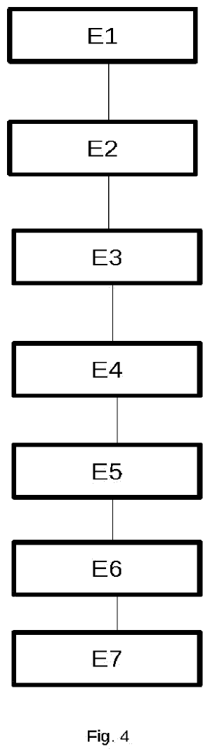

FIG. 4 is a flow diagram illustrating a method for manufacturing a flexible laminate.

In these figures, the elements that are identical bear the same numeric references.

The following realizations are examples. Although the description refers to one or more embodiments, that does not necessarily mean that each reference relates to the same embodiment, or that the features apply only to a single embodiment. Simple features of different embodiments can also be combined or interchanged to provide other realizations.

In the following description, reference is made to a first and a second intermediate layer. This is a simple indexing to differentiate and name the elements that are similar but not identical. This indexing does not imply any priority of one element over another and such designations can easily be swapped without departing from the framework of the present description. Nor does this indexing imply any order in time for example for appreciating the disposition of the different layers that make up the flexible laminate or even for appreciating the operation thereof.

In the following description, “frontal layer” is understood to mean the surface of the flexible laminate exposed first to the solar rays when the flexible laminate is in the installed state. Similarly, the “rear layer” in the following description is understood to mean the layer opposite the frontal layer, that is to say the surface which is impacted last by the solar rays in their passage through the laminate when the laminate is in the installed state.

Then, “transparent” in the following description is understood to mean a material, preferably of neutral color, through which the light can pass with a maximum intensity absorption of 10% for the wavelengths lying in particular between 315 nm and 1300 nm.

Furthermore, “flexible” in the following description is understood to mean an element which, upon the application of a certain bending radius, does not lose its physical integrity or its electrical performances. In the present description, the element should support, without damage, a bending radius of 100 cm.

Referring to FIGS. 1 and 2, a flexible laminate 1 of photovoltaic cells 3 is represented. The flexible laminate 1 comprises at least a layer of photovoltaic cells 3 connected to one another, and a frontal layer 5 and a rear layer 7 encapsulating the layer of photovoltaic cells 3. The frontal 5 and rear 7 encapsulation layers sandwich the layer of photovoltaic cells 3 (visible in FIGS. 2 and 3) in order to protect the photovoltaic cells 3 notably from outside attacks and also keep these photovoltaic cells 3 together. When the flexible laminate 1 is in the installed state, the light rays penetrate first through the frontal encapsulation layer 5 and, when they are not picked up by the layer of the photovoltaic cells 3, leave through the rear encapsulation layer 7. Thus, at least the frontal encapsulation layer 5 is transparent in order to allow the solar rays to reach the layer of photovoltaic cells 3 to allow their photovoltaic energy to be converted into electrical energy. Moreover, this flexible laminate 1 has at least one lateral edge 8. Generally, the flexible laminate 1 is of substantially parallelepipedal form, and in this case it has four lateral edges 8 (as represented referring to FIG. 1). However, this flexible laminate 1 can have other geometrical forms and therefore a different number of lateral edges 8, such as, for example, a single lateral edge 8 in the case of a circular form or three lateral edges 8 in the case of a triangular form, or even a greater number of lateral edges 8 in the case of more complex forms. Furthermore, this flexible laminate 1 can for example be obtained by a conventional lamination method, that is to say by raising the temperature of a stack of the different layers forming this flexible laminate 1 then by pressure on this stack for a predetermined time in a vacuum or in an inert atmosphere for example, as is described in more detail later. Moreover, the flexibility of the laminate is obtained by virtue of the constituent materials of the different layers that make up the laminate. The use of such a laminate, and notably its flexibility, makes it possible to facilitate its transport and its installation because the fragility thereof is diminished. Furthermore, the flexibility of this laminate also allows it to be adapted to different supports, including dished supports. Such a flexible laminate 1 can form a photovoltaic module or a photovoltaic panel corresponding to an assembly of several photovoltaic modules together. Indeed, within the meaning of the present description, a photovoltaic module is understood to be the most elementary unit of electrical energy production (producing direct current), composed of an assembly of photovoltaic cells 3 interconnected with one another and completely protected from the outside environment, that is to say as defined by the standard IEC-TS61836.

Also, the flexible laminate 1 also comprises at least one transparent layer of polymer-based varnish 9 deposited on one of the frontal 5 and/or rear 7 encapsulation layers. The transparent layer of varnish 9 is disposed on the outside of the flexible laminate 1, that is to say so as to be the first to be in contact with the outside attacks. Thus the transparent layer of varnish 9 is configured to ensure a protection of the flexible laminate 1 and in particular against the degradations associated with ultraviolets or with moisture and which can lead to a yellowing at least of the frontal layer 5 which can be detrimental to the good operation of the photovoltaic panel, or even to the impacts or scratches which can damage the integrity of the photovoltaic cells 3 or of the frontal encapsulation layer 5 for example. In fact, the presence of this transparent layer of varnish 9 makes it possible to preserve the physical integrity of the flexible laminate 1 over time. Furthermore, this transparent layer of varnish 9 can offer the flexible laminate 1 antifouling properties.

According to a particular embodiment, the at least one lateral edge 8 of the flexible laminate 1 is covered with the transparent layer of varnish 9. This disposition of the transparent layer of varnish 9 makes it possible to prevent any ingress of moisture between the layers forming this flexible laminate 1 which could lead to a delamination of this flexible laminate 1 at the lateral edges 8. Thus, the disposition of the transparent layer of varnish 9 on the at least one lateral edge 8 of the flexible laminate 1 contributes to the resistance of this flexible laminate 1 to outside attacks over time.

The at least one transparent layer of varnish 9 consists of a polymer-based varnish chosen from among the varnishes of polyurethane type, the varnishes of acrylic type, the varnishes of polyester type, the varnishes of silicone type, or even the varnishes of epoxy type. The use of such varnishes makes it possible to guarantee a good compatibility of the latter with the composite materials notably forming the photovoltaic cells 3 and the frontal 5 and rear 7 encapsulation layers. That, among other things, makes it possible to ensure a good resistance of the flexible laminate 1 to the different degradation mechanisms mentioned previously. Furthermore, some varnishes exhibit self-healing properties. Thus, they have a higher resistance to impacts, to abrasive wear or even to scratching. Furthermore, in case of degradation of this varnish following friction or excessive shocks for example, it is possible to make repairs by adding this varnish to damaged zones possibly with the prior removal of the damaged zones. That therefore makes it possible to facilitate and simplify the operations of maintenance and repair of this flexible laminate 1. In fact, such reworks are not possible in the case of the laminates that have protective layers in the form of films that are known from the prior art. Furthermore, such varnishes offer a good resistance to chemical attacks, and notably acids.

According to a particular embodiment, the transparent layer of varnish 9 has a thickness less than 1 mm, preferably less than 0.5 mm. Such thicknesses for the transparent layer of varnish 9 can be obtained using different deposition techniques described later. Furthermore, such a thickness for the transparent layer of varnish 9 is not detrimental to the final thickness of the flexible laminate 1 and limits the necessary quantities of varnish, which, among other things, allows for a control of production costs of such a flexible laminate 1.

Moreover, according to different variants, the varnish can comprise at least one self-extinguishing additive, such as, for example, hexabromocyclododecane, in order to have fireproofing properties. Also, the varnish can comprise at least one additive that makes it possible to enhance the diffusion of light.

According to yet another variant, the varnish can comprise at least one additive that makes it possible to create photons of certain spectral ranges to the spectral ranges of conversion of the photovoltaic cells 3, that is to say that allow for a “up” or “down” conversion. In the case of an “up” conversion, two photons of fairly low energy are combined together to form a photon of sufficient energy to ensure the operation of the photovoltaic panel. Such an “up” conversion therefore occurs for the infrared radiations arriving on the flexible laminate 1. Moreover, such additives allowing for an “up” conversion can for example be chosen from among the doped rare earth ions, doped rare earth oxides, or even doped rare earth fluorides. Also, in the case of a “down” conversion, an energy-rich photon is separated into two photons of lower energy in order to ensure the operation of the photovoltaic panel. Such a “down” conversion therefore occurs for the ultraviolet radiations.

According to yet another variant, the varnish can comprise at least one additive that absorbs or reflects the ultraviolet radiations having a wavelength less than 315 nm, such as, for example, benzophenones, benzotriazoles, or even hindered amine light stabilizers, also known by the acronym HALS, such as, for example, PEDA or other amine derivatives, or 2,2,6,6-tetramethylpiperidine amino-ether. The use of such a coating makes it possible to prevent the delamination of the different layers that make up the flexible laminate 1 and possibly the degradation of certain components of the flexible laminate 1 because of the energy of the ultraviolet radiations. Indeed, some wavelengths of the ultraviolet radiations are known to embrittle plastic compounds and in particular make them breakable. Furthermore, the absorption of these radiations does not have a significant impact on the conversion efficiencies of the flexible laminate 1 because the wavelengths of these radiations are outside of the spectral conversion ranges, and therefore the spectral ranges of interest, of the photovoltaic cells 3. Also, when the varnish is intended to be deposited on the rear encapsulation layer 7, the latter can comprise an additive such as pigments to provide a color to the photovoltaic module by reflection or by transmission.

As a variant or in addition, the varnish can comprise glass balls. The addition of glass balls in the composition of the varnish allows for a better adhesion on the surface of the flexible laminate 1 by increasing the roughness of the face of the flexible laminate 1 having this transparent layer of varnish 9. Such improved adhesion allows for improved safety of the maintenance operatives on steep roofs for example or on mobile supports or in case of surface moisture. Moreover, the addition of glass balls makes it possible to open up these photovoltaic modules to new applications such as, for example, pavings. Indeed, this modification of the adhesion, through the addition of glass balls in the varnish, allows the public to walk on such photovoltaic blocks in total safety because of the roughness created by these glass balls. Thus, the addition of glass balls in the composition of the varnish can be interesting when this transparent layer of varnish 9 is disposed at least on the frontal encapsulation layer 5 of the flexible laminate 1.

Referring to FIG. 2, the flexible laminate 1 is represented according to a particular embodiment. According to this particular embodiment, the flexible laminate 1 has a transparent layer of varnish 9 disposed in contact with the frontal encapsulation layer 5 and a transparent layer of varnish 9 disposed in contact with the rear encapsulation layer 7. Thus, all of the flexible laminate 1 is protected from external attacks, such as moisture for example. According to this particular embodiment, the flexible laminate 1 has only one transparent layer of varnish 9. However, according to other embodiments, the flexible laminate 1 can have a greater number of transparent layers of varnish 9, and in particular when additives are added to the latter in order to confer upon it one or more of the properties mentioned previously. Alternatively, different additives can be mixed in a single varnish according to their chemical compatibility so that the deposition of a single layer of varnish is sufficient in order to give the flexible laminate 1 different properties if necessary.

Also, according to this particular embodiment, the frontal 5 and rear 7 encapsulation layers are layers of glass fiber fabric pre-impregnated with an encapsulation resin, such as, for example, a resin of epoxy type. The use of a fabric of pre-impregnated glass fibers makes it possible to facilitate the encapsulation of the photovoltaic cells 3 in order to ensure the cohesion between the glass fiber fabric and the layer of photovoltaic cells 3.

Referring to FIG. 3, the flexible laminate 1 is represented according to another particular embodiment. According to this other particular embodiment, the flexible laminate 1 further comprises a first 11 and a second 13 intermediate layer disposed respectively between the frontal encapsulation layer 5 and the layer of photovoltaic cells 3 and between the rear encapsulation layer 7 and the layer of photovoltaic cells 3. These first 11 and second 13 intermediate layers can, for example, be composed of a dry fabric of dry glass fibers, that is to say with no encapsulation resin. The addition of such layers can for example allow for a better diffraction of the light at the layer of photovoltaic cells 3 in order to enhance the production efficiencies of the flexible laminate 1 for example. Also, such first 11 and second 13 intermediately layers of glass fibers can make it possible to improve the resistance to shocks of this flexible laminate 1.

Also, as represented with reference to the particular embodiment of FIG. 3, the flexible laminate 1 has a single transparent layer of varnish 9 disposed on the surface of the frontal encapsulation layer 5. According to a variant that is not represented here, the flexible laminate 1 can have a transparent layer of varnish 9 disposed on each frontal 5 and rear 7 encapsulation layer. Moreover, as for the embodiment of FIG. 2, the flexible laminate 1 can have more than one transparent layer of varnish 9 on one or other of the encapsulation layers.

According to a variant that is not represented here, the transparent layer of varnish 9 can be deposited on a single face of the flexible laminate 1 comprising a layer of photovoltaic cells 3 sandwiched between the frontal encapsulation layer 5 and the rear encapsulation layer 7, such as, for example, on the frontal encapsulation layer 5. In this case, the rear encapsulation layer 7 can possibly be coated with a protective film which ensures the protection of the non-varnished face of the flexible laminate 1 in its environment. Also, this protective film can be incorporated in the flexible laminate 1 before or after the laying of the transparent layer of varnish 9.

Alternatively to this variant that is not represented, only the rear encapsulation layer 7 can be covered with varnish, such as, for example, varnish comprising pigments. In this case, the frontal encapsulation layer 5 is covered with the protective film. According to this alternative, the protective film is transparent so as not to be detrimental to the efficiencies of the flexible laminate 1.

According to one or other of these variants that are not represented, the flexible laminate 1 can also comprise the first 11 and second 13 intermediate layers.

Referring to FIG. 4, a method for manufacturing a flexible laminate 1 of photovoltaic cells 3 is schematically illustrated that comprises a layer of photovoltaic cells 3 connected to one another, a frontal layer 5 and a rear layer 7 encapsulating the layer of photovoltaic cells 3.

As indicated previously, the flexible laminate 1 is obtained by a conventional lamination method. Thus, the method comprises a step El of construction of the stack of the frontal 5 and rear 7 encapsulation layers and of the layer of photovoltaic cells 3. If the flexible laminate 1 comprises the first 11 and second 13 intermediate layers, these first 11 and second 13 intermediate layers are disposed in the stack during this step E1. The method then implements a step E2 of deposition of this stack of layers in an oven, then a vacuum-forming step E3 in order to evacuate the air present in the oven and between the different layers of the stack. This step E3 can be implemented for a predetermined time or can be controlled by pressure sensors disposed inside the oven: once the pressure inside the oven has reached a predetermined value, the method then implements a step E4 of heating of the stack in order to allow the polymerization of the encapsulation resin then a step E5 of pressing on the stack in order to compress the different layers one against the other for a predetermined time in order to form the flexible laminate 1. This predetermined time can for example correspond to the time of the polymerization reaction of the encapsulation resin used. During these heating and pressing steps, the vacuum is kept operating so as to prevent any formation of air bubbles between the different layers of the laminate, these air bubbles being able to be due to air present in the oven or to gas emissions resulting from the heating of the different layers and notably of the encapsulation resin. The method then implements a step of stopping of the heating and of ventilation of the oven in order to return the pressure inside the oven to atmospheric pressure then a step of extraction of the laminate thus obtained. Optionally, the method can comprise a step of cutting of the flexible laminate 1 in order to make it possible to obtain a photovoltaic module with the desired dimensions and form. Then, the method comprises a finishing step E6 in which a polymer-based varnish is applied to at least one of the frontal 5 or rear 7 encapsulation layers.

The polymer-based varnish is in liquid form. The use of a liquid varnish notably makes it possible to facilitate its deposition on the frontal 5 and/or rear encapsulation layer. Also, the varnish has a composition such that, when it dries or polymerizes, it forms the transparent layer of varnish 9. Furthermore, the use of a varnish makes it possible, during this finishing step E6, to modify the thickness of this transparent layer of varnish 9 as desired in order to reinforce certain properties of the flexible laminate 1 for example. Furthermore, the use of this varnish in liquid form makes it possible to have access to a larger panel for the solvents that make up this varnish in order, for example, to improve the chemical compatibility and adhesion of this varnish with the resin and/or the fabric of glass fibers on which this varnish is deposited. Furthermore, the use of this varnish makes it possible to have access to many liquid phase application techniques.

The finishing step E6 can be performed by spraying varnish on the frontal 5 or rear 7 encapsulation layer, by deposition of the varnish with a brush on the frontal 5 or rear 7 encapsulation layer, or even by curtain coating on the frontal 5 or rear 7 encapsulation layer. These different deposition techniques are easy to implement and are notably possible through the use of a varnish in liquid form. Moreover, such techniques make it possible to obtain a uniform deposition over all of the surface of the encapsulation layer on which the latter is performed. According to a particular embodiment, the finishing step E6 is performed by spraying varnish on the frontal 5 or rear 7 encapsulation layer. Performing this finishing step E6 by spraying allows for a simple and rapid deposition of the varnish on the frontal 5 or rear 7 encapsulation layer, which allows notably for a reduction of the costs of production of such flexible laminates 1. When this finishing step E6 is performed by curtain coating, it can be possible to simultaneously perform the deposition of several layers of varnish on the frontal 5 or rear 7 encapsulation layer. Thus, when several layers of varnish are applied to the frontal 5 or rear 7 encapsulation layer, this finishing step E6 can be performed in a single pass of the flexible laminate 1 at the station performing the finishing step E6. Furthermore, these different deposition techniques make it possible to deposit the thickness that is desired and in a controlled way on the frontal 5 or rear 7 encapsulation layer.

These different techniques for deposition of the varnish in liquid form allow this varnish to protect the lateral edges 8 of the photovoltaic module. In fact, the varnish in liquid form can at least by capillarity wet, or even be deposited deliberately on, the flexible laminate 1 which allows this varnish to be deposited on the lateral edges 8, also called fields, of this flexible laminate 1 and notably prevent the ingress of moisture between the different layers of this flexible laminate 1 through the lateral edges 8 of this flexible laminate 1. Also, these deposition techniques can also make it possible to control the thickness of the transparent layer of varnish 9 deposited on the lateral edge 8 of this flexible laminate 1. Such a protection of the fields of the flexible laminate 1 is not possible with the protective films known from the prior art. The deposition of the varnish on the fields of the flexible laminate 1 make it possible to create a moisture-tight barrier, which, among other things, makes it possible to prevent separation of these different layers because of the moisture and therefore enhance the longevity of the photovoltaic module.

Also, the method comprises here, and optionally, an additional step of texturing E7 of the varnish. This additional texturing step E7 can for example be performed during the polymerization of this varnish, or even before the polymerization of this varnish. This additional optional texturing step E7 can for example be performed by calendering. This additional texturing step E7 can for example make it possible to add an esthetic side or even new functionalities to the flexible laminate 1, such as, for example, a better adhesion by mixing glass balls with the varnish. Also, this additional texturing step E7 can also make it possible to enhance the conversion efficiencies of this flexible laminate 1 by virtue of the diffraction phenomena induced by the texturing performed on this transparent layer of varnish 9.

The different embodiments described above are given in a purely illustrative and nonlimiting manner. Indeed, it is perfectly possible for the person skilled in the art to use additives for the varnish other than those identified in the present description. Moreover, it is perfectly possible for the person skilled in the art to use additives that make it possible to confer on the transparent layer of varnish 9 properties other than those identified in the present description without departing from the framework of the present invention. Furthermore, the person skilled in the art will be able to use components other than dry or impregnated glass fibers for the frontal 5 and rear 7 encapsulation layers or for the first 11 and second 13 intermediate layers without departing from the framework of the present invention. Also, the frontal 5 and rear 7 layers or the first 11 and second 13 additional layers have the same construction. However, according to other variants, these different layers can have different compositions. Moreover, the person skilled in the art will be able to use other types of encapsulation resins other than those described in the present description without departing from the framework of the invention. Finally, the person skilled in the art will be able to use other means for implementing the finishing step E6 or the additional step E7 without departing from the framework of the present invention.

Thus, obtaining a flexible laminate 1 having an enhanced resistance to outside conditions, and notably climatic conditions, while conserving the requisite properties for a flexible and lightweight laminate, is possible using the flexible laminate 1 described previously. Moreover, obtaining such a flexible laminate 1 is possible, notably using the method for manufacturing this flexible laminate 1 described above.

1.-14. (canceled)

15. A flexible laminate of photovoltaic cells, comprising:
a layer of photovoltaic cells connected to one another;
a frontal layer and a rear layer encapsulating the layer of photovoltaic cells, the frontal layer and the rear layer sandwiching the layer of photovoltaic cells; and
at least one transparent layer of polymer-based varnish deposited on one of the frontal layer and/or the rear layer, the at least one transparent layer being disposed on an outside of the flexible laminate and being configured to ensure a protection of the flexible laminate.

16. The flexible laminate according claim 15, wherein the at least one transparent layer consists of a polymer-based varnish chosen from among varnishes of polyurethane type, varnishes of acrylic type, varnishes of polyester type, varnishes of silicone type, or varnishes of epoxy type.

17. The flexible laminate according to claim 15, wherein the polymer-based varnish comprises at least one additive that absorbs or reflects ultraviolet radiation.

18. The flexible laminate according to claim 15, wherein the polymer-based varnish comprises at least one self-extinguishing additive.

19. The flexible laminate according to claim 15, wherein the polymer-based varnish comprises at least one additive that makes it possible to enhance diffusion of light.

20. The flexible laminate according to claim 15, wherein the polymer-based varnish comprises at least one additive that makes it possible to convert photons of certain spectral ranges to current-conversion spectral ranges of the photovoltaic cells.

21. The flexible laminate according to claim 15 wherein the polymer-based varnish comprises glass balls.

22. The flexible laminate according to claim 15, wherein the polymer-based varnish comprises an additive such as pigments configured to be deposited on the rear layer.

23. The flexible laminate according to claim 15, wherein at least one lateral edge of the flexible laminate is covered with the at least one transparent layer of polymer-based varnish.

24. A method for manufacturing a flexible laminate of photovoltaic cells comprising a layer of photovoltaic cells connected to one another, a frontal layer and a rear layer encapsulating the layer of photovoltaic cells, the method comprising a finishing step in which a polymer-based varnish, in liquid form, is applied to at least one of the frontal layer or the rear layer.

25. The manufacturing method according to claim 24, wherein the finishing step is performed by spraying varnish onto the frontal layer or the rear layer.

26. The manufacturing method according to claim 24, wherein the finishing step is carried out by curtain coating.

27. The manufacturing method according to claim 24, wherein the finishing step is carried out by brush deposition of the polymer-based varnish on the frontal layer or the rear layer.

28. The manufacturing method according to claim 24, further comprising an additional step of surface texturing of the polymer-based varnish.
